(19) United States
(12) Patent Application Publication
(10) Pub. No.: US 2025/0294668 A1
(43) Pub. Date: Sep. 18, 2025

(54) Harness PCB

(71) Applicant: Turner Logic, LLC, Boerne, TX (US)

(72) Inventors: Christopher Turner, Boerne, TX (US); Brian Long, Boerne, TX (US); David Bird, Boerne, TX (US)

(21) Appl. No.: 19/079,445

(22) Filed: Mar. 13, 2025

Related U.S. Application Data
(60) Provisional application No. 63/564,899, filed on Mar. 13, 2024.

(51) Int. Cl. H05K 1/02; A63F 7/02

(52) U.S. Cl. CPC H05K 1/0218; A63F 7/027

(57) ABSTRACT

The present invention relates to a Harness PCB that replaces the traditional wiring harness used in a pinball machine. The Harness PCB comprises circuit traces, connectors for all playfield components, LED assemblies, and connectors for device boards. The Harness PCB is attached to the bottom of the playfield and may comprise a single PCB or multiple interconnected PCBs. All playfield components, cabinet components, device boards, and LEDs are connected to the Harness PCB in such a manner that all components that may fail during normal operation are both modular and replaceable. The Harness PCB can be replicated by connecting the device boards directly to breakout boards to create an identical software and hardware environment as the full Harness PCB.

### CROSS-REFERENCES TO RELATED APPLICATIONS

This application claims the benefit of U.S. Provisional Application Ser. No. 63/564,899, filed Mar. 13, 2024 entitled Harness PCB which is incorporated by reference herein.

### STATEMENT REGARDING FEDERALLY SPONSORED RESEARCH OR DEVELOPMENT

Not applicable.

### BACKGROUND OF THE INVENTION

### 1. Field of the Invention.

The present invention relates to the wiring and control of the components for a pinball machine.

### 2. Background of the Invention

A pinball machine comprises a cabinet supported by four legs, a back box assembly, a glass top assembly, a playfield, and cabinet circuitry. In a standard pinball machine, much of the cabinet circuitry is attached to the bottom surface of the playfield due to the playfield containing numerous components that require electricity and require communication with a processor. The playfield contains various components including a plurality of fixed, stationary, electrical, mechanical, or electro-mechanical components that may interact with the pinball(s) to score points and/or activate certain features of the game. “Playfield Components” may include ball return assemblies, action coils (e.g., flippers, slingshots, pop bumpers), ball devices (e.g., plunger and auto launch, trough, vertical up kick, ball lock, kickback, scoop lock), diverters, ramps, gates, toys, spinners, targets (e.g., drop, stationary, variable, kicking, rollover, popup), accelerometers, magnets (actuated or fixed), motors (e.g., servos, stepper, motor), sensors, switches (e.g., rollover, eddy, kickback, button, IR, induction, solenoid, trough, or opto), and audiovisual components (e.g., screens, speakers, and lights). The sensors may be enabled to detect the location of the pinball, speed and direction of the pinball, levelness of the playfield, and movement of the playfield (e.g., detect nudging, bumps, or knocks). In addition, the cabinet also contains various components that require electricity and communication with a processor. “Cabinet Components” may include buttons that the player interacts with (e.g., flipper buttons, start button, launch button, action button), money handling devices (e.g., coin door, dollar bill acceptor, card readers, contactless payment systems), menu and diagnostic controls, tilt sensors, shaker motors, and interactive lighting.

In a standard pinball cabinet, lengthy wiring harnesses are used to connect individual elements to a processor/power source with each component usually requiring power, data in, data out, signal, ground, or any combination thereof. In most embodiments, the playfield components are connected to an intermediary peripheral control device that is connected to a processor. These peripheral control devices are usually mounted to the playfield and to the cabinet and add to the complexity of the wiring harness. Additionally, if any part of the peripheral control device fails, the entire control device board requires removal from the wiring harness and playfield for repair or replacement.

Another source of complexity for the wiring harness are the lights mounted to the playfield. In some embodiments, each individual light on a playfield is connected to at least one processor and at least one power source. In other embodiments, lights wired in traditional playfields may be wired in series to reduce complexity and length of wire with the obvious disadvantage of an entire string of lights going dark if one fails. As a result, standard playfields are a tangled agglomeration of wires and harnesses making it difficult to service, time consuming to manufacture, heavy, and expensive.

### SUMMARY OF THE INVENTION

The present invention relates to a novel way to reduce wiring harnesses through prefabricated printed circuit boards (PCBs) that may have LED assemblies, switches, board sockets, and connectors (hereinafter “Harness PCB”). In the preferred embodiment, all pinball machine inputs, outputs, peripheral control devices, and controlled devices are connected to the Harness PCB, which provides connection back to at least one processor and at least one power supply. Each playfield component is connected to the Harness PCB through a connector for quick diagnosis and replacement. In the preferred embodiment, the connectors are placed along the Harness PCB close to where the playfield component is located on the playfield. Each peripheral control device is connected to a device board that is connected to the Harness PCB in a modular and replaceable method.

Additionally, LEDs are connected directly to the Harness PCB to illuminate the playfield such that the LEDs are modular and replaceable, or are connected to a separate smaller modular replaceable PCB that is connected to the Harness PCB. Another embodiment of the Harness PCB comprises the device boards mounted directly to modular breakout boards containing connectors for all components in addition to connectors for power and communication with all other breakout boards and the processor and power supply. In summary, all playfield components, cabinet components, device boards, and LEDs are connected to the Harness PCB in such a manner that all components that may fail during normal operation are both modular and replaceable.

### BRIEF SUMMARY OF THE DRAWINGS

FIG. 1 shows an external isometric view of a pinball machine.

FIG. 2 shows an internal view of the front of a pinball machine.

FIG. 3 shows a top isometric view of a playfield from a pinball machine.

FIG. 4 shows a bottom view of a playfield without the Harness PCB

FIG. 5 shows a top view of the Harness PCB.

FIG. 6 shows a bottom view of the Harness PCB.

FIG. 7 shows a bottom isometric view of a playfield with the Harness PCB mounted to the bottom surface of the playfield.

FIG. 8 shows a closeup view of the right side of the bottom surface of the Harness PCB.

FIG. 9 shows a closeup view of the top surface of the Harness PCB shown in FIG. 8.

FIG. 10 shows an alternative embodiment of the LED assembly positioned in the Harness PCB where the LED assembly is mounted in a breakaway tab and the replacement LED assembly is mounted to a PCB that connects to the Harness PCB.

FIG. 11 shows the top and bottom view of an embodiment of a replacement LED PCB assembly.

FIG. 12 shows a further alternative embodiment of the LED assemblies where the LED assembly is mounted in a breakaway tab and the replacement LED assembly is mounted to a PCB that connects to a connector on the Harness PCB.

FIG. 13 shows the top and bottom view of another embodiment of a replacement LED PCB assembly.

FIG. 14 shows a further alternative embodiment of the LED assemblies where the original LED assembly is mounted to a PCB that connects to a connector on the Harness PCB.

FIG. 15 shows an embodiment of the Harness PCB where the device boards are mounted directly to breakout boards.

### DETAILED DESCRIPTION OF THE INVENTION

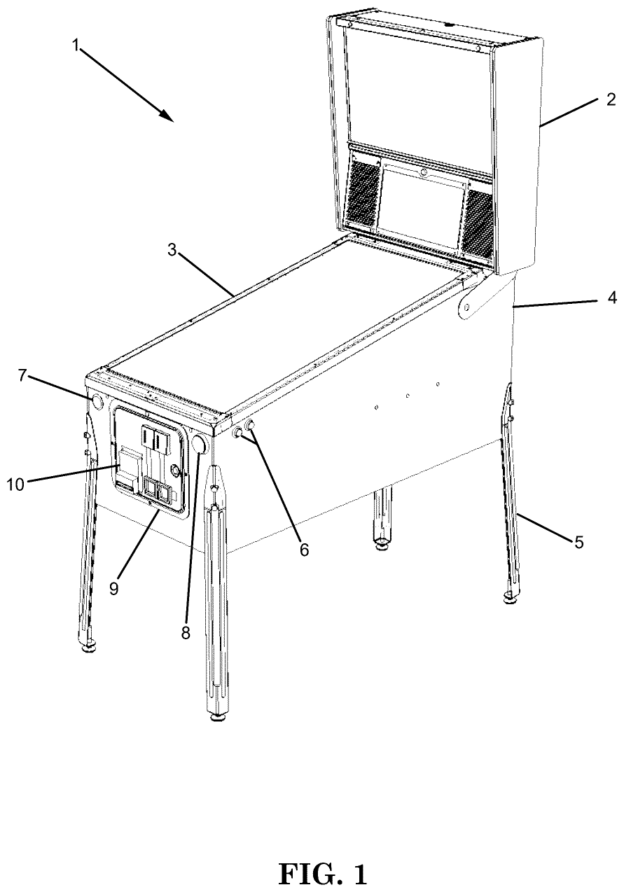

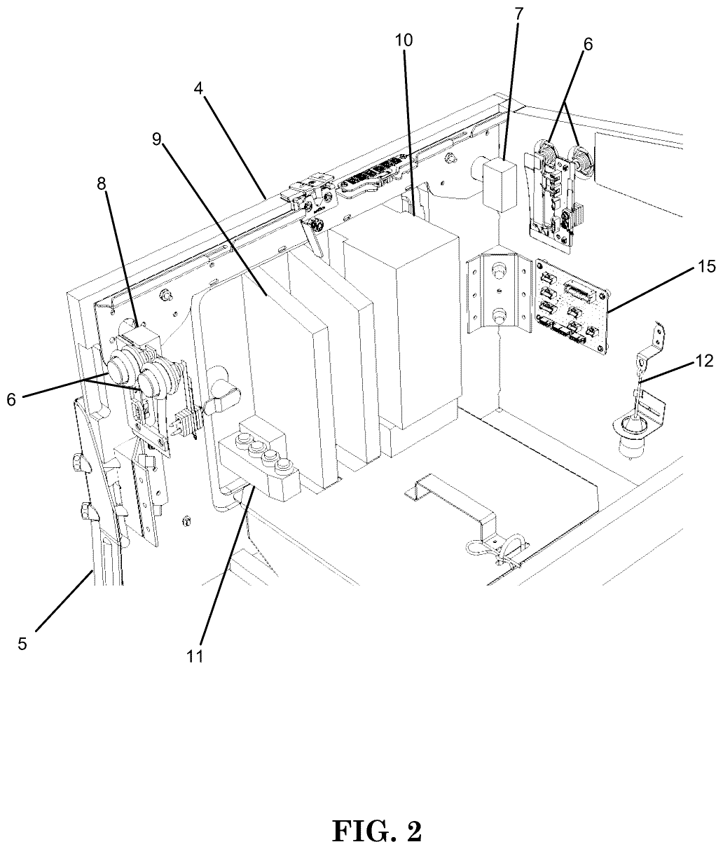

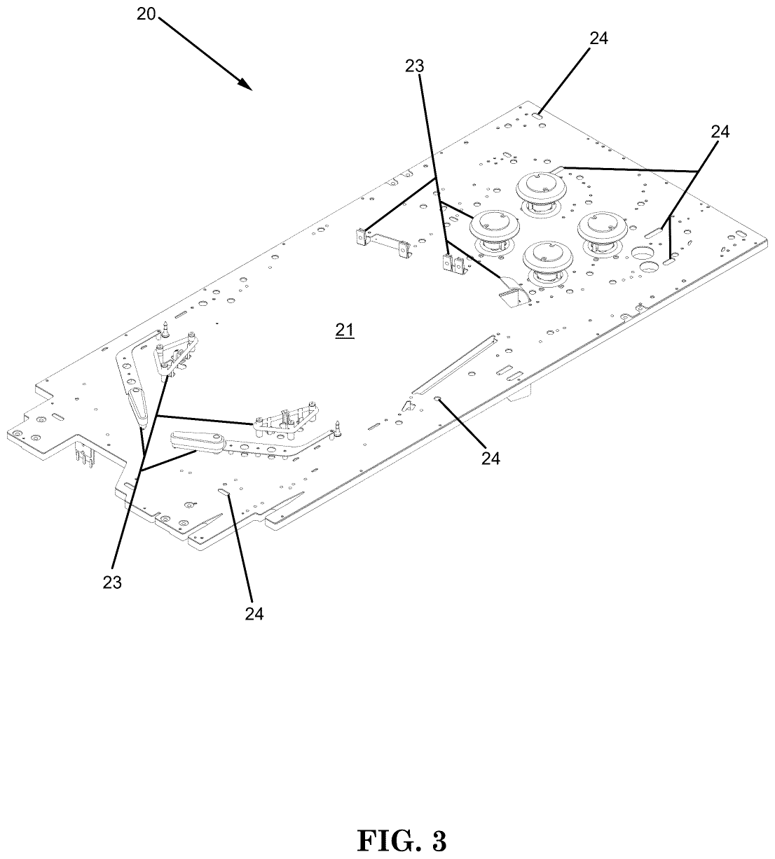

As seen in FIGS. 1-2, a pinball machine 1 comprises a cabinet 4 supported by four legs 5, a back box assembly 2, a glass top assembly 3, a playfield 20 (as seen in FIG. 3) within the cabinet 4, and cabinet circuitry. Cabinet circuitry generally refers to circuit boards, processors, and other electrical components that control operation of the pinball machine 1. The cabinet 4 comprises various input and output devices interfaced with at least one processor, such as flipper buttons 6, a start button 7, launch button 8, coin door 9, and dollar bill acceptor 10.

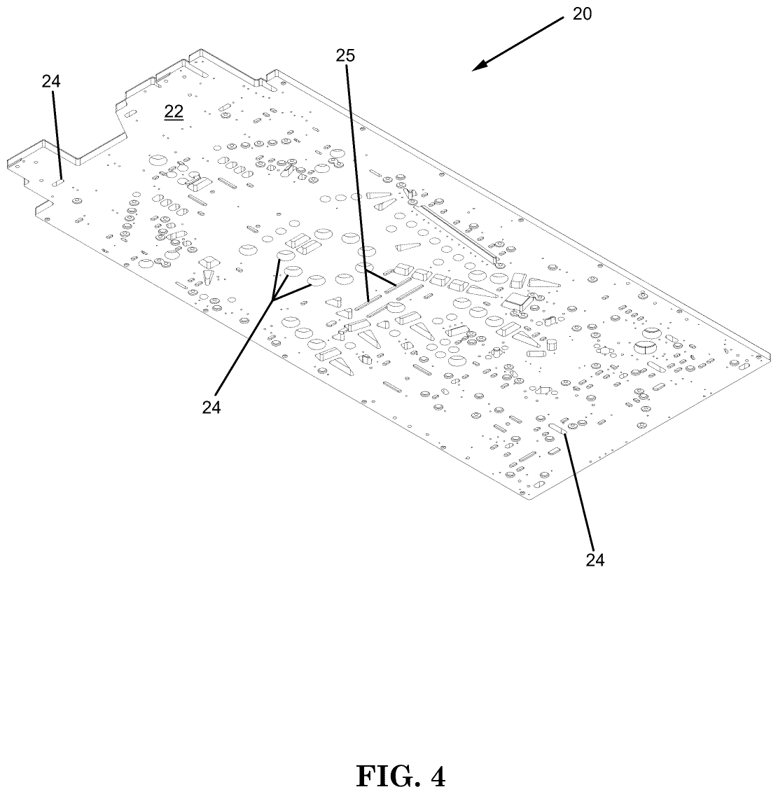

As seen in FIGS. 3-4, the playfield 20 comprises a top surface 21, a bottom surface 22, and various playfield components 23 required for gameplay and operation. Playfield holes 24 extend through the top surface 21 and bottom surface 22 of the playfield 20. Playfield holes 24 may have a variety of shapes depending on the purpose. Clearance cuts 25 are positioned on the bottom surface 22 of the playfield 20 and do not extend through to the top surface 21.

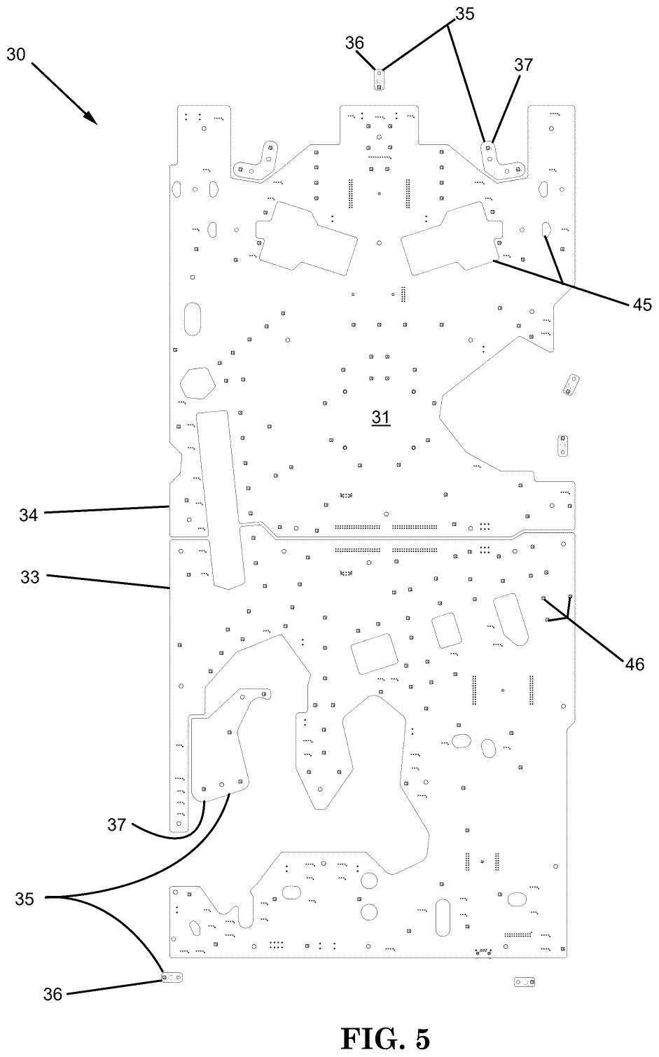

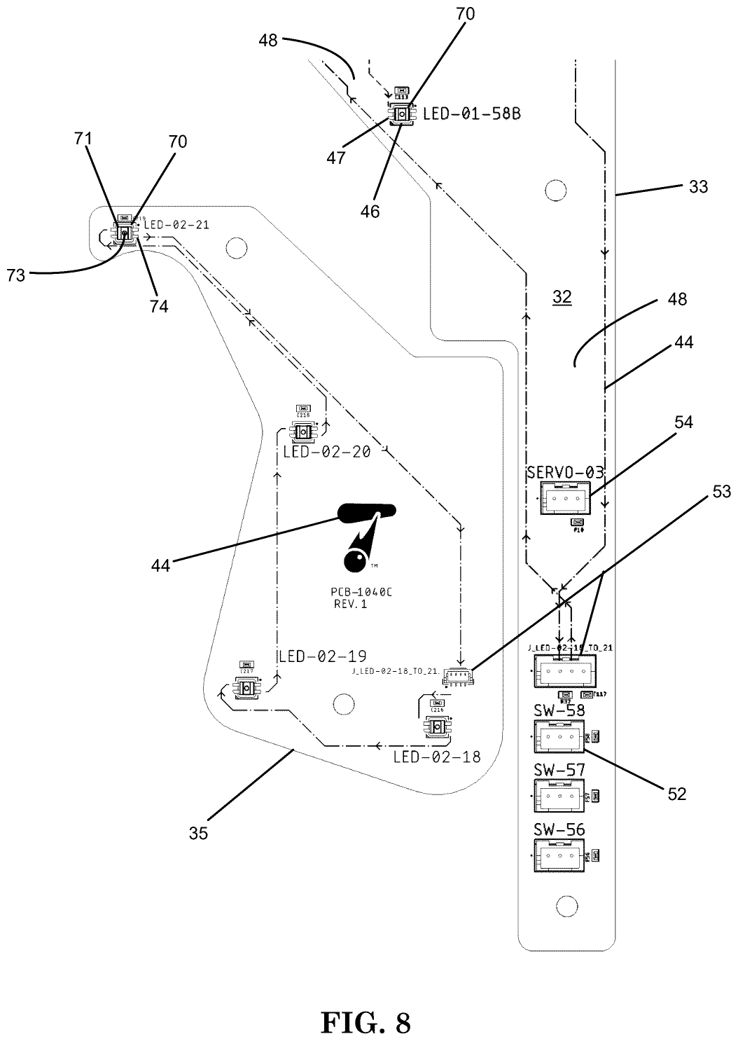

As seen in FIGS. 5-7, the Harness PCB 30, having a top surface 31 and a bottom surface 32, is mounted to the bottom surface 22 of the playfield 20 such that the top surface 31 of the Harness PCB 30 is in contact with, or abutting, the bottom surface 22 of the playfield 20. The clearance cuts 25 on the bottom surface 22 of the playfield 20 allow for the top surface 31 of the Harness PCB 30 to fit flat against the bottom 22 surface of the playfield 20 to the extent any components of the Harness PCB 30 protrude from the top surface 31 of the Harness PCB 30. Alternatively, the Harness PCB 30 may be connected to the playfield such that there is space between the bottom surface 22 of the playfield 20 and the top surface 31 of the Harness PCB 30. PCB holes 45 extend through the top surface 31 and bottom surface 32 of the Harness PCB 30. LED holes 46 extend through the top surface 31 and bottom surface 32 of the Harness PCB 30 and are generally square in shape with soldering connections 47 (as seen in FIG. 8) on at least one side of the LED hole 46, preferably on the bottom surface 32. PCB holes 45, including LED holes 46, may have a variety of shapes depending on the purpose and may correspond to playfield holes 24. The PCB holes 45 allow for clearance around playfield components 23 that extend below the playfield 20 as required by the playfield design and may allow for pass through of wires.

The Harness PCB 30 is manufactured with circuit traces 48 based on a predetermined design. The circuit traces 48 comprise at least one power trace, at least one signal trace, and at least one ground trace. The circuit traces 48 may also be layers or planes as known by a person of ordinary skill in the art. In one embodiment, the Harness PCB 30 has more than one power trace for use with different voltages such as 48V, 12V, 5V. Circuit traces 48 provide power (e.g., 5V, 12V or 48V), data connections, and ground as appropriate for each playfield component 23 and other pinball machine components. In one embodiment, the Harness PCB 30 is supplied with the highest voltage necessary for the components (e.g. 48V) and then reduced by power supplies connected to the Harness PCB 30 and distributed via circuit traces 48 for the other voltages as necessary (e.g. 12V and 5V). In other embodiments, other voltages may be supplied directly to the Harness PCB 30.

The Harness PCB 30 further comprises a first board 33 and a second board 34 connected by a wiring harness to one or more data jumpers 42 and a power jumper 43. The first board 33 contains a main power connector 40 that connects to the primary power supply in the cabinet 4, or the backbox 2, and a primary data connector 41 that connects to at least one processor in the cabinet 4 or backbox 2. The main power connector 40, primary data connector 41, data jumpers 42, and power jumper 43 are in communication with circuit traces 48.

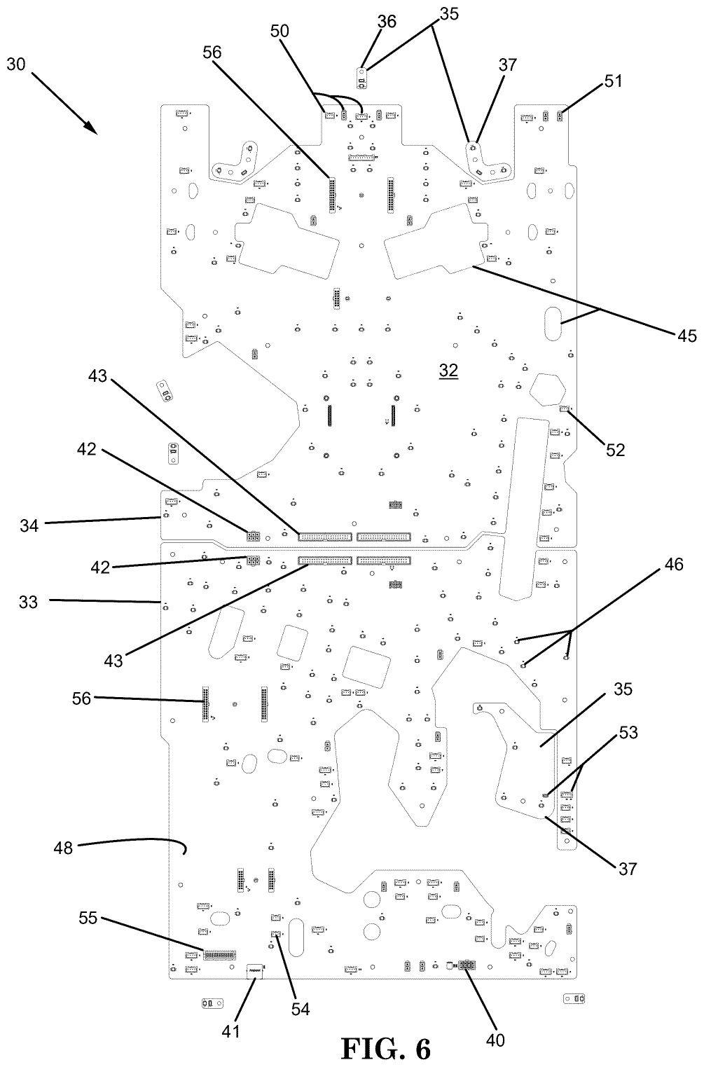

As seen in FIG. 2, a remote PCB 15 can be mounted to the cabinet 4 (hereinafter “Cabinet PCB” 15) and connected to the Harness PCB 30 via a wiring harness with data and power to a remote board connector 55 (as seen in FIG. 6). This board can be used to connect to all the cabinet components such as buttons (e.g., flipper buttons 6, start button 7, launch button 8, action button), money handling devices (e.g., coin door 9, dollar bill acceptor 10, card readers, contactless payment systems), menu and diagnostic controls 11, tilt sensors 12, shaker motors, and interactive lighting.

As seen in FIGS. 6 and 8, based on a predetermined design, connectors 50 for playfield components 23 and other pinball machine components are positioned on the bottom surface 32 of the Harness PCB 30, and are in communication with the circuit traces 48. There are multiple types of connectors 50, depending on the type of pinball machine component. For example, there are connectors 50 for playfield components 23 to include coil connectors 51, switch connectors 52, magnet connectors, LED connectors 53, servo connectors 54, motor connectors, and connectors for other electrical and/or electro mechanical components. In some embodiments, switches, such as microswitches, magnetic switches, inductive switches, and optoelectronic switches, may be mounted directly on the Harness PCB 30 based on a predetermined design. In locations where a playfield component 23 is located on or above the top surface 21 of the playfield 20, a playfield hole 24 can be made through the playfield 20 with a corresponding hole 46 through the Harness PCB 30. A connector 50 is located near the hole 46 such that the component 23 wire can be run through the hole 24 in the playfield 20 and the hole 46 in the Harness PCB 30 and plugged into the connector 50 to reduce the wire length between the playfield component 23 and the connector 50 on the Harness PCB 30. Each connector 50 is connected to the appropriate circuit traces 48, such as the power, ground or signal (e.g. coils generally need 48V whereas LEDs need 5V).

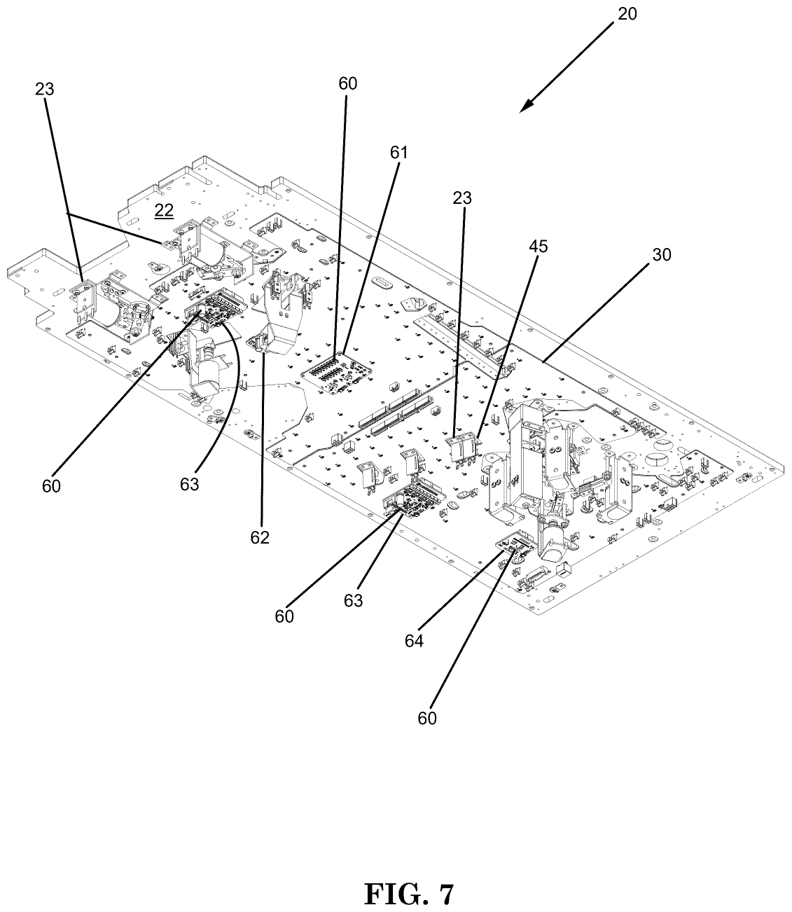

As seen in FIG. 7, device boards 60 may be mounted to the bottom surface 32 of the Harness PCB 30 by a connector such as a board socket 56 based on a predetermined design. Alternatively, device boards may be connected to a connector on the Harness PCB 30 via a wiring harness. Device boards 60 may include peripheral control boards, logic boards, switch input boards, LED control boards, coil driver boards 63, servo/stepper/motor driver and controller boards 64, power supply boards 62, or a board containing any other device required for the operation of a pinball machine. Additionally, some device boards 60 can perform multiple functions, such as the Switch and LED Board 61 shown in FIG. 7 that performs the function of a logic board, switch input board, and LED control board. Each device board 60 is in communication with an appropriate connector 50, if any, via circuit traces 48, and may be in communication with a processor of the pinball machine via circuit traces 48. Each device board 60 may be easily removed and replaced if the device board 60 fails. Each device board 60 is connected to the appropriate circuit traces 48, such as the power, ground or signal.

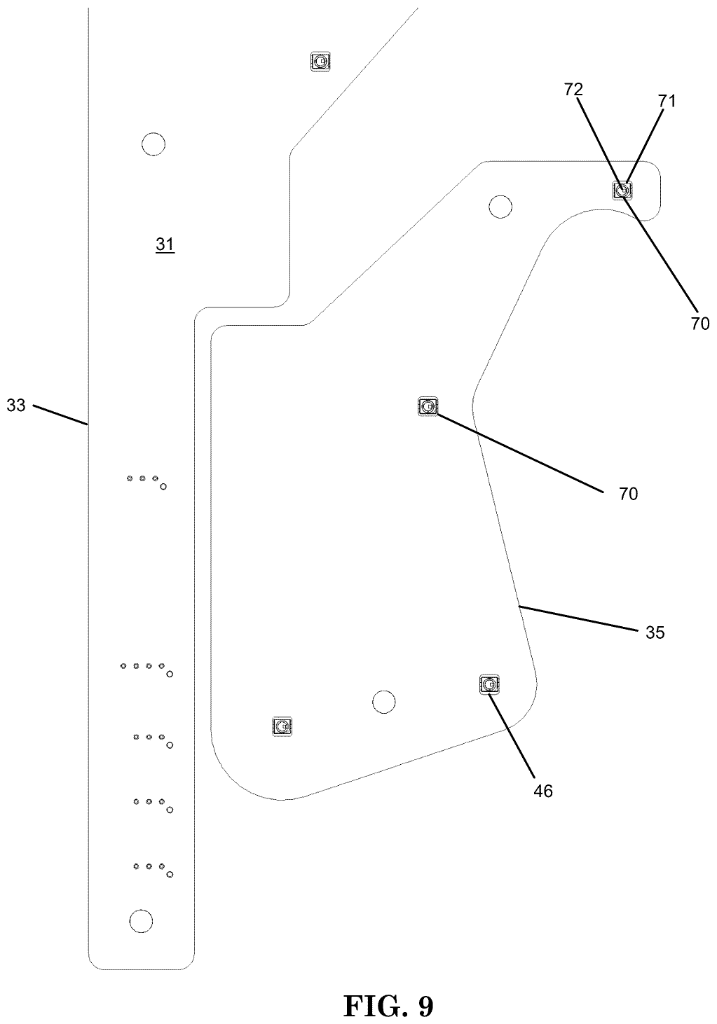

As seen in FIGS. 8-9, the preferred embodiment of the modular and replaceable LED assembly 70 comprises a base 71, multicolor LEDs 72, LED controlling circuitry 73, and solder connections 74. Since the LED assembly 70 contains all circuitry 73 required to control and drive the multicolor LEDs 72, all LED related elements that may fail during normal operation are contained within the replaceable LED assembly 70. The LED assemblies 70, based on a predetermined design, are mounted to the Harness PCB 30 in the LED hole 46 and connected via solder between the LED assembly 70 solder connections 74 and the Harness PCB 30 solder connections 47. The LED assembly 70 is positioned such that the LEDs 72 face up through the top surface 32 of the Harness PCB 30. The LED 72 of the LED assembly 70 shines through LED hole 46 and illuminates a playfield hole 24 in the playfield 20. Each LED assembly 70 is connected to the appropriate circuit traces 48, such as the power, ground or signal. The use of circuit traces 48 allows the LED assemblies 70 to be wired in series or parallel. In the embodiment shown in FIGS. 8-9, the LED assembly 70 is a reverse-mount RGB LED that is soldered directly to exposed pads on the bottom surface 32 of the Harness PCB 30. The soldered LED assembly 70 can be removed by either desoldering the connection between the solder connection 74 and solder connection 47 or cutting the solder connections 74 on the LED and then replaced by soldering on a new LED assembly 70.

In the preferred embodiment, a single Harness PCB 30 connects to all of the playfield components 23 and may be connected to all other pinball machine components. However, due to manufacturing and cost constraints, it is usually more feasible to split the Harness PCB 30 into two or more boards. In the embodiment shown in FIGS. 4 and 6-7, the Harness PCB 30 is split into a first board 33 and a second board 34. The first board 33 and second board 34 are connected through two data jumper connectors 42 and one power jumper connector 43 such that both boards act as a single harness PCB. Additionally, LED assemblies 70 that are not mounted directly to the primary Harness PCB 30, due to reasons such as manufacturability or ease of access, may be mounted to a separate LED PCB 35 that are connected to the Harness PCB 30 with a single connector 53 (via wiring harness) such that the LED assemblies 70 on the separate PCB 35, in communication with circuit traces 48, are part of the Harness PCB 30 LED circuit either in series or parallel. As seen in FIGS. 6-7, the separate LED PCB 35 can have various sizes and shapes to include a compact board 36 with a single LED assembly 70 or a larger board 37 with multiple LED assemblies 70. The larger separate LED PCB 37 boards may have standard shapes for use across multiple platforms or unique game specific designs.

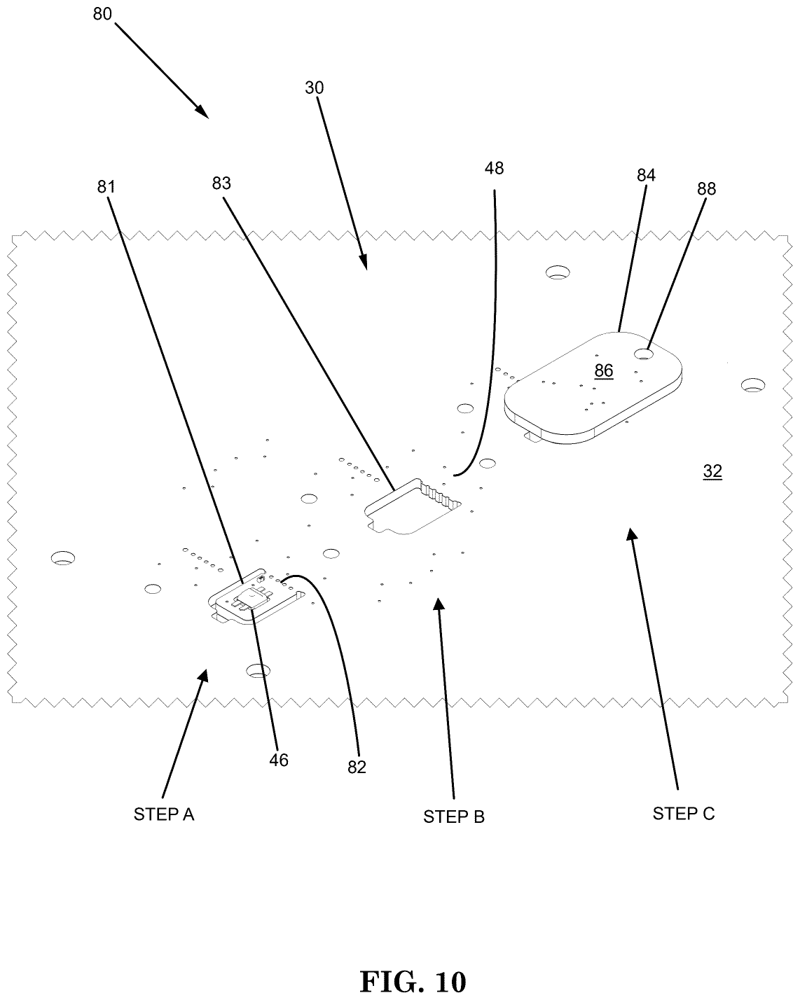

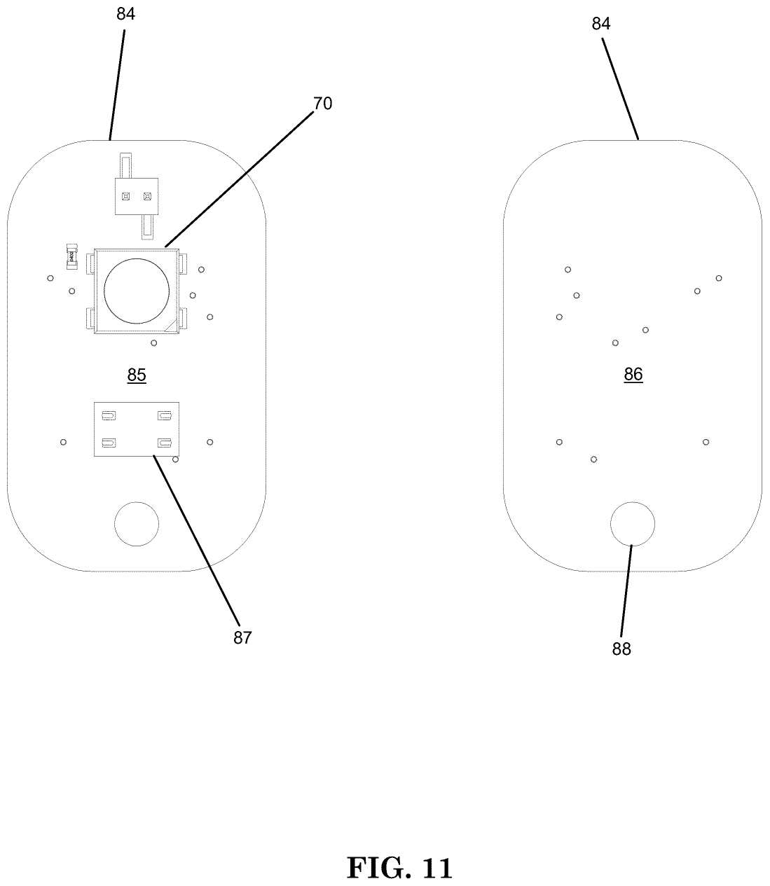

FIG. 10 shows an alternative embodiment 80 of the Harness PCB 30 concerning the LED assembly 70 via sequential steps labeled A, B, and C. As seen at Step A, the alternative embodiment 80 of the Harness PCB 30 comprises a tabbed portion 81 connected to the Harness PCB 30 via perforation 82 in which the LED assembly 70 and LED hole 46 are positioned within the tabbed portion 81. If the LED assembly 70 fails, the tabbed potion 81 may be broken away from the Harness PCB 30 at the perforation 82 and removed. Once removed, a hole 83 remains in the Harness PCB 30 as seen at Step B. As seen in FIG. 11, a replacement LED assembly PCB 84 comprises a top surface 85, a bottom surface 86, pins 87, a screw hole 88, and an LED Assembly 70. The pins 87 and LED assembly 70 are mounted to the top surface 85. As seen in FIG. 10 at Step C, the replacement LED assembly PCB 84 may then be positioned with the top surface 85 over the hole 83, with the pins 87 in contact with circuit traces 48 of the Harness PCB 30. The replacement LED assembly PCB 84 may be secured to the Harness PCB 30 or playfield 20 preferably via screw in the screw hole 88. The replacement LED assembly 84 is now controlled by the Harness PCB 30, via circuit traces 48, which determines when the LED Assembly 70 is energized.

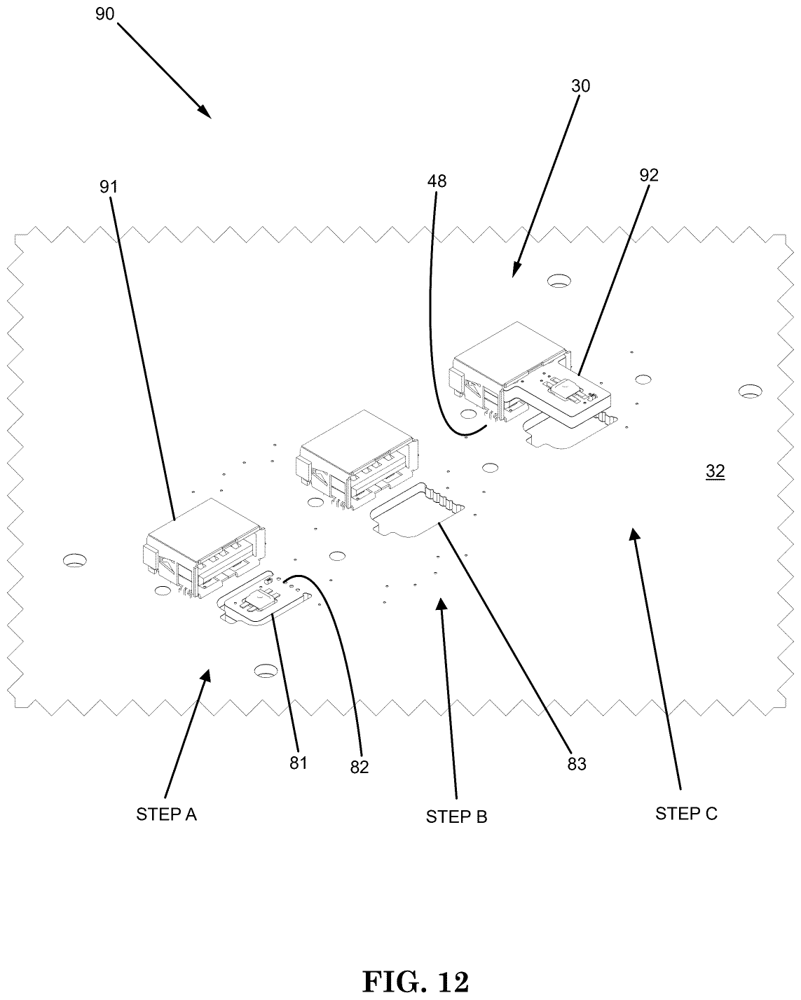

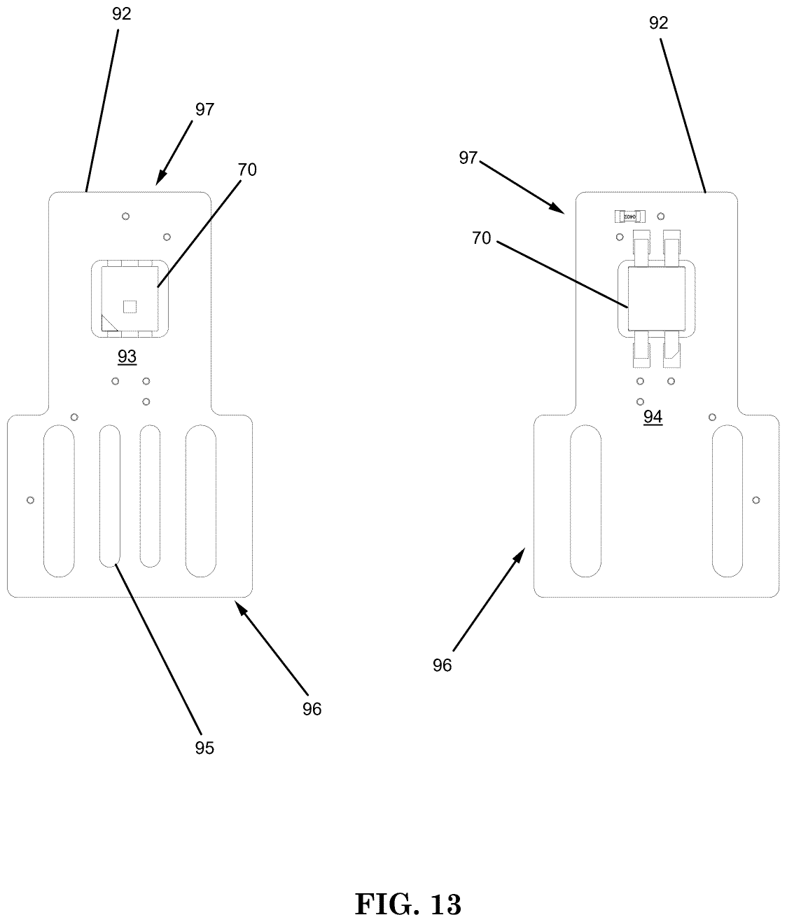

FIG. 12 shows a further alternative embodiment 90 of the alternative embodiment 80 of Harness PCB 30 shown in FIG. 10. A physical connector 91 may be affixed to the bottom surface 32 of the Harness PCB 30 next to the tabbed portion 81 as seen at Step A. The physical connector 91 is connected to the same circuit traces 48 in the Harness PCB 30 as the LED assembly 70 positioned within the tabbed portion 81. In one embodiment, as seen in FIG. 12, the connector 91 is a USB-A receptacle. If the LED Assembly 70 fails, the tabbed portion 81 is broken away from the Harness PCB 30 exposing the hole 83 in the Harness PCB 30 as seen at Step B. As seen in FIG. 13, a replacement LED assembly PCB 92 comprises a top surface 93, a bottom surface 94, exposed circuit traces 95 in a proximal end 96, and an LED assembly 70 in a terminal end 97. The proximal end 96 may contain a connector that firmly secures the replacement LED assembly PCB 92 to the connector 91 mounted to the Harness PCB 30 and provides communication between the Harness PCB 30 and the replacement LED assembly PCB 92. As seen in FIG. 12 at Step C, the replacement LED assembly PCB 92 may then be mounted to the connector 91 attached to the bottom surface 32 of the Harness PCB 30 such that the top surface 93 of the replacement LED assembly PCB 92 is positioned over the hole 83 and the LED assembly 70 aligns with the hole 83. In one embodiment, as seen in FIG. 12, the circuit traces 95 and proximal end 96 are designed such that the USB-A receptacle 91 firmly secures the replacement LED assembly PCB 92 in place and provides communication between the Harness PCB 30 and the replacement LED assembly PCB 92. Because the traces 48 that go to the connector 91 are the same traces 48 that go to the tabbed portion 81, the replacement LED assembly PCB 92 is energized by the Harness PCB 30 in the same manner as the tabbed portion 81, requiring no further software or hardware changes other than those shown in Steps A-C in FIG. 12.

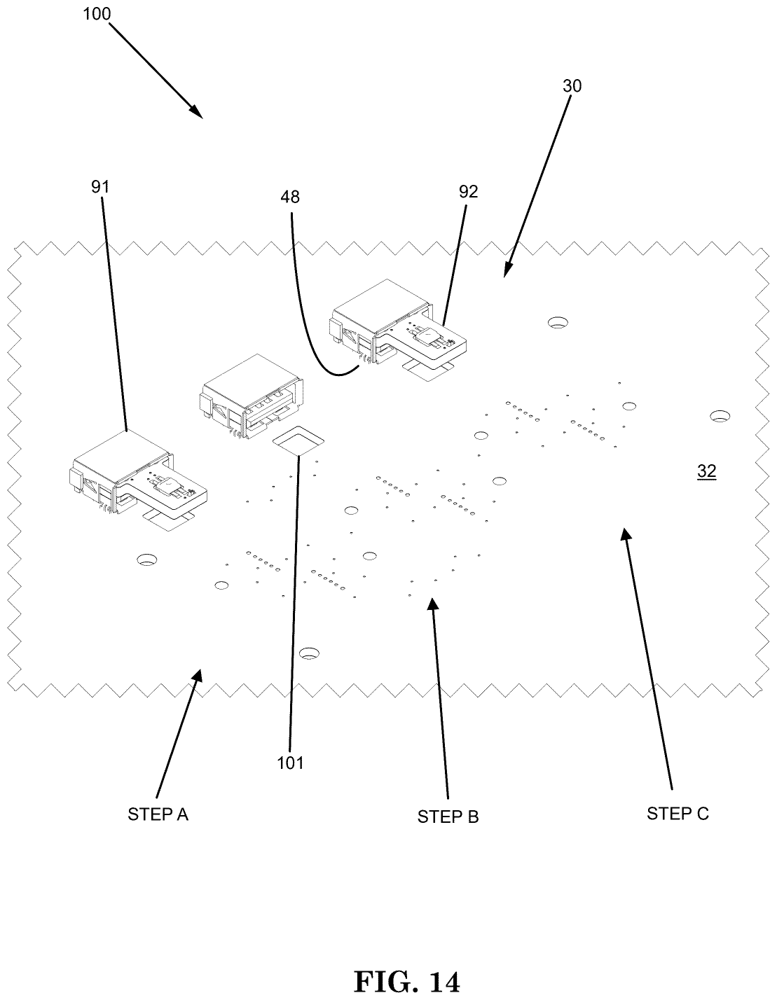

FIG. 14 shows a further alternative embodiment 100 of the embodiment 90 of Harness PCB 30 shown in FIG. 12. In this embodiment, a hole 101 replaces the tabbed portion 81 in the Harness PCB 30 wherein the hole 101 is aligned with the connector 91. As seen at Step A, the original manufactured state comprises an LED assembly PCB 92, as shown in FIG. 13, mounted to the connector 91 to be controlled by the Harness PCB 30 such that the top surface 93 of the replacement LED assembly PCB 92 is positioned over the hole 101 and the LED assembly 70 aligns with the hole 101. If the LED assembly PCB 92 fails, it is simply removed as seen at Step B, and replaced as seen at Step C with a new LED assembly PCB 92.

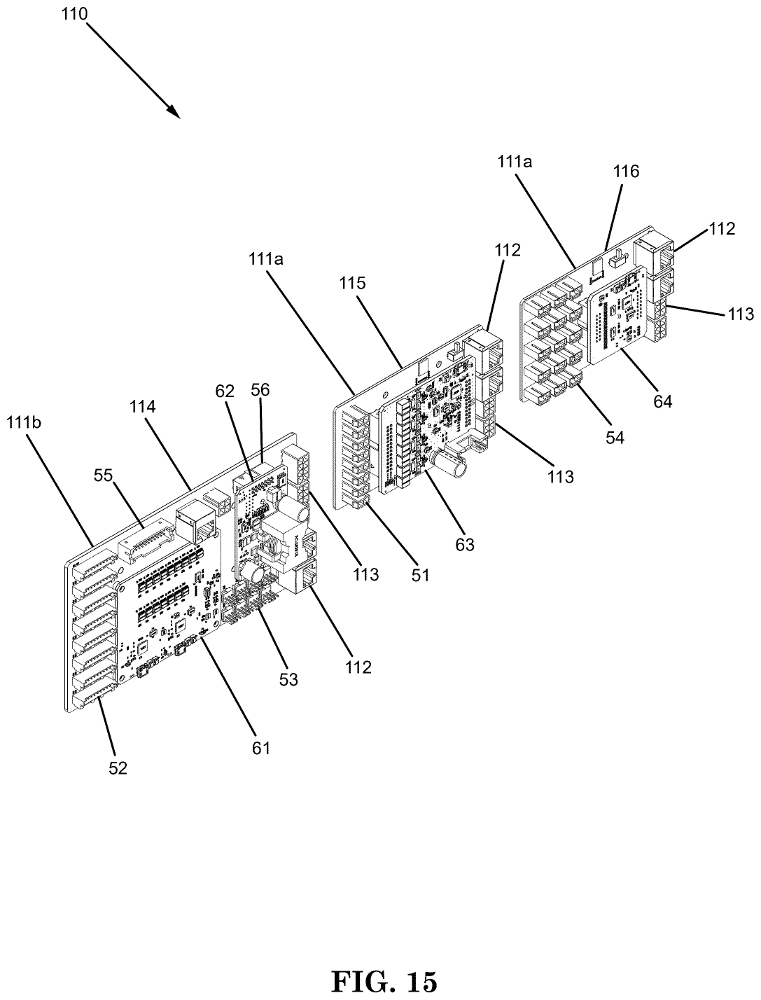

A further alternative embodiment of the Harness PCB 30, seen in FIG. 15, comprises the device boards 60 mounted to multiple breakout boards 111 (hereinafter “Breakout Board Harness PCB 110”) via a connector such as a board socket 56. Playfield components 23, other pinball machine components, and LED Assemblies 70 are connected to the appropriate connectors 50 located on the Breakout Board Harness PCB 110, and the breakout boards 111 are connected to each other via wire harnesses using data connectors 112 and power connectors 113 with one breakout board 111 also connected to at least one processor and power supply usually via wire harness. In the embodiment seen in FIG. 15, two different types of breakout boards 111 are shown. The first type of breakout board 111a is designed to mount a single device board 60 such as the breakout board 116 for the servo control board 64 with servo connectors 54 and the breakout board 115 for the coil driver board 63 with coil connectors 52. A second type of breakout board 111b is designed to mount multiple device boards 60 such as the breakout board 114 for the Switch and LED Device Board 61 with LED connectors 53 and switch connectors 52 and Power Supply Board 62 with remote board connectors 55.

The Breakout Board Harness PCB 110 can be used during the development phase of a pinball machine 1 to rapidly test the machine using the final production device boards 60 to create an identical software and hardware environment without having to first create a Harness PCB 30. Alternatively, the Breakout Board Harness PCB 110 can be used as the final production solution for low volume pinball machines 1, such as custom made “home brew” machines, low volume production runs, and even full scale production deployment in situations where creating the Harness PCB 30 is not desired. A further alternative application is using the Breakout Board Harness PCB 110 as a method to retrofit or replace the existing manufacturer's wiring harness in a pinball machine 1 in situations where keeping the original wiring harness is undesirable for reasons such as complexity, unavailability of parts, unreliability, inefficiency, or inability to be modified.

The Harness PCB 30 provides a safe, reliable, and repeatable way to make connections. In a traditionally wired playfield, the numerous wires that connect all the components increase the risk for shorts, accidental pulls/snags when moving the playfield, and wiring mistakes during manufacturing or servicing. With the Harness PCB 30, the total number and lengths of wires required to make all the connections are drastically reduced. The connectors 50 located on the Harness PCB 30 are located near the playfield components 23 that connect to them, so each component 23 only requires a small jumper harness to connect to the Harness PCB 30, greatly reducing the chance of a short or pull snag. Also, in the preferred embodiment, a resettable fuse is mounted on the bottom surface 32 of the Harness PCB 30 for each individual connector 50 associated with low-current components, such as switches, LEDs, and servos. Higher-current components, such as coils, magnets, and motors have an active current limit circuit on the device board 60 corresponding to driving that component. Therefore, should a short happen to a component or wire, the Harness PCB 30 will automatically cut off current from flowing to the shorted component. Also, the Harness PCB 30 can detect a short or open condition and report it to at least one processor so the user or maintenance technician can be notified by the pinball machine 1. Additionally, the Harness PCB 30 can utilize a printed silkscreen 44 (as seen in FIG. 8) to identify each connector 50, drastically reducing the time required and possibility of mistakes during manufacturing or servicing. The Harness PCB 30 can be completely produced and tested by machines, which drastically reduces the manufacturing complexity, time, and potential for human error when compared with creating a traditional wiring harness.

The structure of the Harness PCB 30 allows for easy replacement of any modular part that fails. For example, if a device board 60 fails, the device board 60 is simply removed from the Harness PCB 30 and a new device board 60 is installed. If a playfield component 23 fails, such as a coil or switch, it is simply disconnected from the appropriate connector 50 and replaced. If an LED fails, the LED assembly 70 may be physically removed and a new LED assembly 70 may be connected and/or soldered on. As seen in FIGS. 6 and 8, the Harness PCB 30 can utilize a printed silkscreen 44 to identify the purpose of each connector 50 making it easier for a user or service technician to visually understand the connections. Additionally, the printed silkscreen 44 may also show the circuit traces for all playfield LEDs 70 wired in series so that if one LED fails, it can be identified easily for replacement.

In an alternative embodiment, all or some of the connectors 50, device boards 60, and/or LED assemblies 70 may be connected to the top surface 31 of the Harness PCB 30. In such instances, the connectors 50, device boards 60, and/or LED assemblies 70 may fit within the clearance cuts 25, playfield holes 24, or the space between the Harness PCB 30 and the bottom surface of the playfield 20

The description of the present invention has been presented for purposes of illustration and description and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated. It will be understood by one of ordinary skill in the art that numerous variations will be possible to the disclosed embodiments without going outside the scope of the invention as disclosed in the claims.

1. A harness PCB, for a pinball machine having a playfield, comprising
a first surface;
a second surface;
circuit traces comprising at least one power, at least one signal, and at least one ground;
at least one device board in communication with at least one of the circuit traces; and
at least one connector on the harness PCB in communication with the at least one device board through at least one of the circuit traces;
wherein the first surface of the harness printed circuit board is mounted adjacent a bottom surface of the playfield.

2. The harness PCB of claim 1 wherein the at least one device board is connected to the harness PCB by a board socket.
